(19) United States
(12) Patent Application Publication
(10) Pub. No.: US 2024/0213175 A1
(43) Pub. Date: Jun. 27, 2024

(54) SEMICONDUCTOR PACKAGE HAVING ALIGNMENT PATTERN

(71) Applicant: Samsung Electronics Co., Ltd., Suwon-si (KR)

(72) Inventor: Daewoong HEO, Suwon-si (KR)

(73) Assignee: Samsung Electronics Co., Ltd., Suwon-si (KR)

(21) Appl. No.: 18/535,231

(22) Filed: Dec. 11, 2023

(30) Foreign Application Priority Data
Dec. 27, 2022 (KR) 10-2022-0185864
Apr. 12, 2023 (KR) 10-2023-0048230

(51) Int. Cl. H01L 23/544; H01L 23/00; H01L 23/498

(52) U.S. Cl. CPC H01L 23/544; H01L 23/49838; H01L 24/32; H01L 24/48; H01L 24/73; H01L 2223/54426; H01L 2224/32225; H01L 2224/48227; H01L 2224/73265; H01L 2924/181

(57) ABSTRACT

A semiconductor package includes a substrate including an upper pad and an alignment pad on an upper surface thereof, a first bonding pad disposed on the upper pad, the first bonding pad including a first trench extending in one direction on an upper surface thereof, at least one first alignment pattern disposed on the alignment pad and disposed to be adjacent to the first bonding pad, a semiconductor chip disposed on the substrate, and a first bonding wire connecting the semiconductor chip to the first bonding pad, wherein the at least one first alignment pattern is aligned with the first trench in a direction in which the first trench extends, and the first bonding wire contacts the first bonding pad and partially fills an inner wall of the first trench.

### CROSS-REFERENCE TO RELATED APPLICATION(S)

This application claims benefit of priority to Korean Patent Application Nos. 10-2022-0185864 filed on Dec. 27, 2022, and 10-2023-0048230 filed on Apr. 12, 2023, in the Korean Intellectual Property Office, the disclosures of each of which are incorporated herein by reference in their entirety.

### BACKGROUND

The present inventive concepts relate to a semiconductor package having an alignment pattern.

As demand for high performance, high speed, and/or multifunctionality of semiconductor devices has increased, the demand for a higher degree of integration of the semiconductor devices has also increased. In manufacturing a semiconductor device having a fine pattern corresponding to the trend for high integration of semiconductor devices, it is required to implement patterns having a fine width or a fine separation distance. In addition, high integration of semiconductor devices mounted in a semiconductor package is required.

### SUMMARY

An aspect of the present inventive concepts is to provide a semiconductor package having an alignment pattern disposed to be adjacent to a bonding pad.

According to an aspect of the present inventive concepts, a semiconductor package includes: a a substrate including an upper pad and at least one alignment pad on an upper surface of the substrate such that the upper pad is adjacent to the at least one alignment pad; a first bonding pad on the upper pad, the first bonding pad including a first trench on an upper surface of the first bonding pad, the first trench extending in a first direction; at least one first alignment pattern on the at least one alignment pad such that the at least one first alignment pattern is adjacent to the first bonding pad and the at least one first alignment pattern is aligned with the first trench in the first direction; a semiconductor chip on the substrate; and a first bonding wire connecting the semiconductor chip to the first bonding pad, the first bonding wire contacting the first bonding pad and partially filling the first trench.

According to another aspect of the present inventive concepts, a semiconductor package includes: a substrate including an upper pad and at least one alignment pad on an upper surface of the substrate such that the upper pad is adjacent to the at least one alignment pad; a bonding pad on the upper pad, the bonding pad including a trench on an upper surface of the bonding pad, and extending in a first direction; at least one alignment pattern on the at least one alignment pad such that the at least one alignment pattern is adjacent to the bonding pad and the at least one alignment pattern is aligned with the trench in the first direction; a semiconductor chip on the substrate and including a chip pad; and a bonding wire connecting the chip pad to the bonding pad, the bonding wire including a stitch portion contacting the bonding pad and a wire portion between the stitch portion and the chip pad, wherein the stitch portion includes a protrusion partially filling the trench, and a width of the at least one alignment pattern is within a range of 15 μm to 20 μm.

According to another aspect of the present inventive concepts, a method of manufacturing a semiconductor package includes: forming an upper pad and at least one alignment pad adjacent to the upper pad on a substrate; forming a lower conductive layer on the upper pad; forming a lower material layer on the at least one alignment pad; forming a lower trench in the lower conductive layer by performing a laser etching process using the alignment pad as a reference point; forming an intermediate conductive layer covering the lower conductive layer, the intermediate conductive layer having an intermediate trench; forming a bonding pad by forming an upper conductive layer covering the intermediate conductive layer, the upper conductive layer having an upper trench; forming an alignment pattern by forming an intermediate material layer and an upper material layer on the lower material layer; and connecting a bonding wire to the bonding pad such that the bonding wire contacts the bonding pad and partially fills an inner wall of the upper trench, wherein the alignment pattern is aligned with the upper trench in a first direction in which the upper trench extends.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a plan view of a semiconductor package according to some embodiments;

FIG. 2 is a partially enlarged view of the semiconductor package illustrated in FIG. 1;

FIG. 3 is a vertical cross-sectional view of the semiconductor package illustrated in FIG. 2, taken along line I-I′;

FIG. 4 is a vertical cross-sectional view of the semiconductor package illustrated in FIG. 2, taken along line II-II′;

FIG. 5 is a vertical cross-sectional view of the semiconductor package illustrated in FIG. 2 along line III-III′;

FIG. 6 is a flow chart of a method of manufacturing a semiconductor package according to some embodiments;

FIG. 7 is a plan view of a semiconductor package according to some embodiments.

FIG. 8 is a vertical cross-sectional view of the semiconductor package illustrated in FIG. 7, taken along line I-I′;

FIGS. 9 to 12 are plan views of semiconductor packages according to some embodiments;

FIG. 13 is a plan view of a semiconductor package according to some embodiments;

FIG. 14 is a vertical cross-sectional view of the semiconductor package illustrated in FIG. 13, taken along line IV-IV′; and

FIG. 15 is a plan view of a semiconductor package according to some embodiments.

### DETAILED DESCRIPTION

Hereinafter, embodiments of the present inventive concepts will be described with reference to the accompanying drawings, wherein like reference numerals refer to like elements throughout. In this regard, the present embodiments may have different forms and should not be construed as being limited to the descriptions set forth herein.

It will also be understood that when an element is referred to as being “on” or “above” another element, the element may be in direct contact with the other element or other intervening elements may be present. It will also be understood that spatially relative terms, such as “upper,” “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

In the drawings, sizes of constituent elements may be exaggerated for convenience of explanation and the clarity of the specification. In the following drawings, the size of each component in the drawings may be exaggerated for clarity and convenience of description. Additionally, when the terms “about” or “substantially” are used in this specification in connection with a numerical value and/or geometric terms, it is intended that the associated numerical value includes a manufacturing tolerance (e.g., ±10%) around the stated value and/or term, unless indicated otherwise. Further, regardless of whether numerical values and/or geometric terms are modified as “about” or “substantially,” it will be understood that these values should be construed as including a manufacturing or operational tolerance (e.g., ±10%) around the stated numerical values and/or geometry. When referring to “within” and/or “C to D”, this means C inclusive to D inclusive unless otherwise specified. Also, embodiments described herein may have different forms and should not be construed as being limited to the descriptions set forth herein.

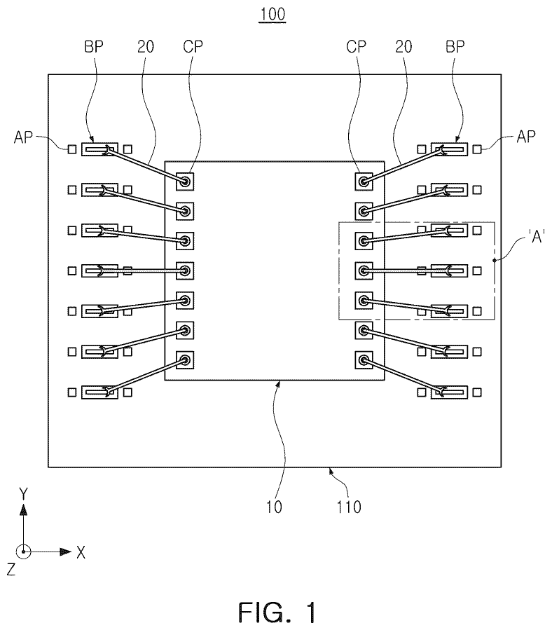

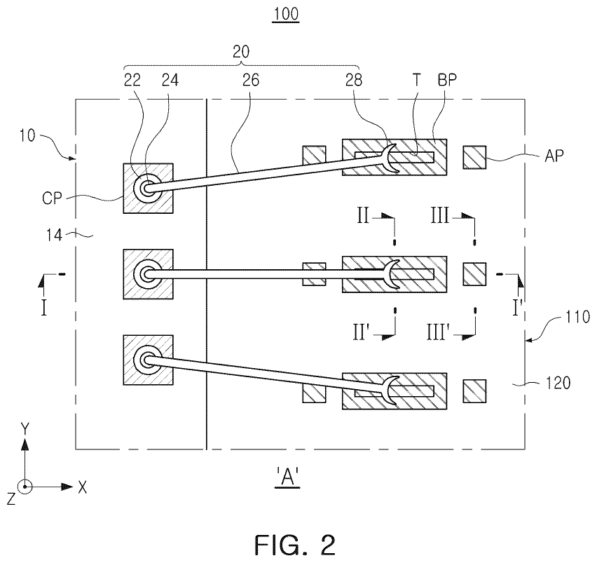

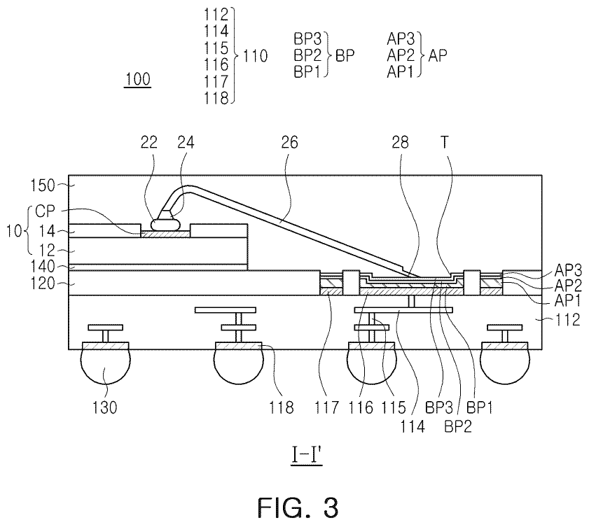

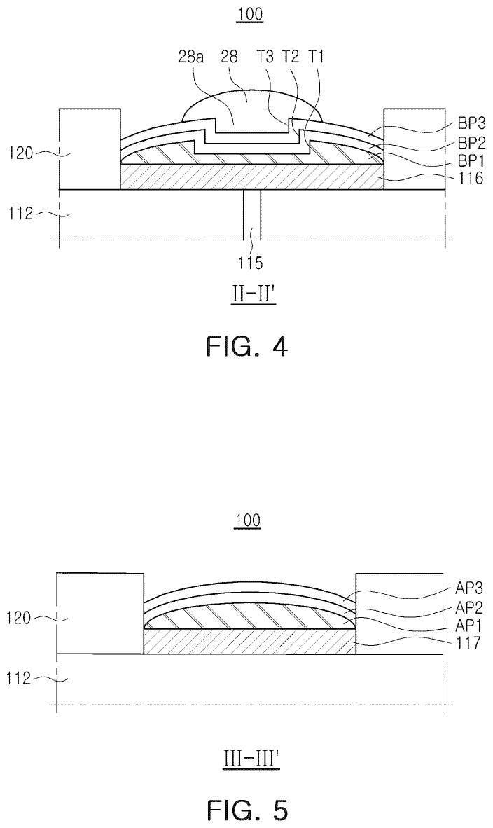

FIG. 1 is a plan view of a semiconductor package according to embodiments. FIG. 2 is a partially enlarged view of the semiconductor package illustrated in FIG. 1. FIG. 2 corresponds to region A illustrated in FIG. 1. FIG. 3 is a vertical cross-sectional view of the semiconductor package illustrated in FIG. 2, taken along line I-I′. FIG. 4 is a vertical cross-sectional view of the semiconductor package illustrated in FIG. 2, taken along line II-II′. FIG. 5 is a vertical cross-sectional view of the semiconductor package illustrated in FIG. 2, taken along line III-III′.

Referring to FIGS. 1 and 2, a semiconductor package 100 according to at least one embodiment of the present inventive concepts includes a semiconductor chip 10, a bonding wire 20, a substrate 110, a passivation layer 120, a bonding pad BP, an alignment pattern AP, and an external connection terminal 130.

In at least one embodiment, the semiconductor chip 10 may be mounted on the substrate 110 by wire bonding. For example, the semiconductor chip 10 may be electrically connected to the substrate 110 through bonding wires 20. Although a single semiconductor chip 10 is illustrated in FIG. 1, the present inventive concepts is not limited thereto. In some embodiments, a plurality of semiconductor chips 10 may be mounted on the substrate 110. For example, the plurality of semiconductor chips 10 may be provided in an array on an upper surface of the substrate, and/or as a stack of semiconductor chips.

The semiconductor chip 10 may be a logic chip or a memory chip. The logic chip may include a microprocessor, an analog device, a digital signal processor, and/or the like. The memory chip may include a volatile memory chip (such as dynamic random access memory (DRAM) or static random access memory (SRAM)), a non-volatile memory chip (such as phase-change random access memory (PRAM), magnetoresistive random access memory (MRAM), ferroelectric random access memory (FeRAM), or resistive random access memory (RRAM)), and/or the like.

The semiconductor chip 10 may include a chip pad CP, and the bonding wire 20 may connect the chip pad CP to the bonding pad BP disposed on the substrate 110. The bonding pads BP may be disposed to correspond to the chip pads CP. For example, the chip pads CP may be spaced apart from each other in a Y-direction, and the bonding pads BP may be spaced apart from each other in the Y-direction to correspond to one of the chip pads CP. The number and arrangement of the chip pads CP and bonding pads BP illustrated are an example and are not limited thereto.

The chip pad CP and the bonding pad BP are illustrated as having a rectangular shape, but are not limited thereto. In some embodiments, the chip pad CP and the bonding pad BP may have various shapes, such as a circular shape, an elliptical shape, a rectangular shape, etc. In at least one embodiment, the bonding pad BP may extend in one direction. For example, the bonding pads BP may be spaced apart from each other in the Y-direction and may extend in an X-direction.

Referring further to FIGS. 3 to 5, the bonding wire 20 may include a ball portion 22, a neck portion 24, a wire portion 26, and a stitch portion 28. The ball portion 22 may contact an upper surface of the chip pad CP, and the neck portion 24 may be disposed on the ball portion 22. The stitch portion 28 may contact the bonding pad BP, and the wire portion 26 may connect the neck portion 24 to the stitch portion 28. A thickness of the stitch portion 28 may be less than a thickness of the wire portion 26. In at least one embodiment, a maximum horizontal width of the stitch portion 28 may be greater than a horizontal width of the wire portion 26. The maximum horizontal width of the stitch portion 28 may be about 38 μm to about 40 μm.

The substrate 110 may include a body portion 112, an internal wiring 114, a via 115, an upper pad 116, an alignment pad 117, and a lower pad 118. The substrate 110 may be a substrate for a semiconductor package, such as a printed circuit board (PCB), a ceramic substrate, a tape wiring board, and/or the like. For example, the body portion 112 of the substrate 110 may include a thermosetting resin, such as epoxy resin, a thermoplastic resin, such as polyimide, or a photosensitive insulating layer. In at least one embodiment, the body portion 112 of the substrate 110 may include materials, such as prepreg, Ajinomoto Build-up Film (ABF), FR-4, bismaleimide triazine (BT), photo Imageable dielectric (PID) resin, and/or the like. In at least one embodiment, the body portion 112 may be formed of a plurality of insulating layers.

The internal wirings 114 may extend in a horizontal direction (e.g., the X and/or Y-directions). The vias 115 may connect the internal wirings 114 on different levels. The internal wirings 114 and the vias 115 may be embedded in the body portion 112.

The upper pad 116 and the alignment pad 117 may be disposed on the body portion 112. The upper pad 116 may be electrically connected to at least one of the internal wirings 114 through the via 115. The alignment pad 117 may be disposed to be adjacent to the bonding pad BP. For example, two alignment pads 117 may be spaced apart from each other in a horizontal direction with one bonding pad BP interposed therebetween. The alignment pad 117 may not contact the via 115 and are electrically isolated from (e.g., may not be electrically connected to) the internal wiring 114. The alignment pad 117 may have the same thickness as that of the upper pad 116. For example, lower and upper surfaces of the alignment pad 117 may be located on the same level as that of the lower and upper surfaces of the upper pad 116, respectively. The alignment pad 117 may include the same material as that of the upper pad 116.

The lower pad 118 may be disposed in a lower portion of the body portion 112. The lower pad 118 may be electrically connected to at least one of the internal wirings 114 through the via 115. At least one of the lower pads 118 may be electrically connected to the upper pad 116.

The internal wiring 114, the via 115, the upper pad 116, the alignment pad 117, and the lower pad 118 may include a conductive material, for example, copper (Cu), aluminum (Al), silver (Ag), tin (Sn), gold (Au), nickel (Ni), lead (Pb), titanium (Ti), chromium (Cr), tungsten (W), alloys thereof, and/or the like.

The passivation layer 120 may cover an upper surface of the substrate 110. The passivation layer 120 may expose (e.g., not cover) upper surfaces of the upper pad 116 and the alignment pad 117 and may cover side surfaces of the upper pad 116 and the alignment pad 117. The passivation layer 120 may protect the upper pad 116 and the alignment pad 117.

The bonding pad BP may be disposed on the upper pad 116. A side surface of the bonding pad BP may contact the passivation layer 120, and a portion of an upper surface of the bonding pad BP may contact the stitch portion 28 of the bonding wire 20. The bonding wire 20 may be electrically connected to the substrate 110 through the bonding pad BP and the upper pad 116. In at least one embodiment, the bonding pad BP may extend in one direction. For example, the bonding pads BP may be spaced apart from each other in the Y-direction and may extend in an X-direction, intersecting the Y-direction. However, the present inventive concepts are not limited thereto.

In at least one embodiment, the bonding pad BP may include a lower conductive layer BP1, an intermediate conductive layer BP2, and an upper conductive layer BP3 being sequentially stacked. In at least one embodiment, lower conductive layer BP1 may include nickel (Ni), the intermediate conductive layer BP2 may include palladium (Pd), and the upper conductive layer BP3 may include gold (Au). A thickness of the lower conductive layer BP1 may be greater than thicknesses of the intermediate conductive layer BP2 and the upper conductive layer BP3. In FIG. 3, upper surfaces of the lower conductive layer BP1, the intermediate conductive layer BP2, and the upper conductive layer BP3 are illustrated as being parallel to the upper surface of the substrate 110, but are not limited thereto. In at least one embodiment, as illustrated in FIG. 4, upper surfaces of the lower conductive layer BP1, the intermediate conductive layer BP2, and the upper conductive layer BP3 in the cross-sectional view illustrated in FIG. 3 may be convex. In at least one embodiment, the thickness of the lower conductive layer BP1 may be about 3 μm to about 10 μm. The intermediate conductive layer BP2 may have a thickness of about 1 μm to about 2 μm. The upper conductive layer BP3 may have a thickness of about 1 μm to about 2 μm.

In at least one embodiment, the bonding pad BP may include a trench T on an upper surface thereof. For example, the lower conductive layer BP1, the intermediate conductive layer BP2, and the upper conductive layer BP3 may respectively include a lower trench T1, an intermediate trench T2, and an upper trench T3 on upper surfaces thereof. The intermediate conductive layer BP2 may cover the lower trench T1 of the lower conductive layer BP1, and the intermediate trench T2 of the intermediate conductive layer BP2 may vertically overlap the lower trench T1. The upper conductive layer BP3 may cover the intermediate trench T2 of the intermediate conductive layer BP2, and the upper trench T3 of the upper conductive layer BP3 may vertically overlap the intermediate trench T2. In this specification, the upper trench T3 of the upper conductive layer BP3 may be referred to as a trench T of the bonding pad BP. In at least one embodiment, the lower trench T1 may be formed by partially etching the lower conductive layer BP1 using a laser. In at least one embodiment, a depth of the lower trench T1 may be about 1 μm to about 5 μm. A width of the trench T of the bonding pad BP in a minor-axis direction (e.g., a direction (of the upper trench T3 of the upper conductive layer BP3) orthogonal to a direction in which the trench T extends) may be about 15 μm to about 20 μm.

The trench T of the bonding pad BP may extend in a direction. For example, the trench T may extend along a major axis of the bonding pad BP. In at least one embodiment, the maximum horizontal length of the trench T may be smaller than the maximum horizontal length of the bonding pad BP. The stitch portion 28 of the bonding wire 20 may partially contact the trench T. For example, the stitch portion 28 may include a protrusion 28a partially contacting the upper surface of the bonding pad BP and an inner wall of the trench T. Since the bonding pad BP of the present inventive concepts includes the trench T, a contact area between the stitch portion 28 and the bonding pad BP may increase, thereby increasing a bonding force of the bonding wire 20.

The alignment pattern AP may be disposed on the alignment pad 117 and may not be electrically connected to the substrate 110. A side surface of the alignment pattern AP may contact the passivation layer 120. In the plan view, the alignment pattern AP may have a quadrangular shape, but is not limited thereto. The alignment pattern AP may be used as a reference point for laser etching in the process of forming, e.g., the lower trench T1. The alignment pattern AP may be disposed to be adjacent to the bonding pad BP. The alignment pattern AP may be spaced apart from an adjacent bonding pad BP in a major axis direction of the adjacent bonding pad BP. In at least one embodiment, for each bonding pad BP, two alignment patterns AP may be disposed to be spaced apart from each bonding pad BP in the X-direction. In at least one embodiment, for each bonding pad BP, the wire portion 26 of the corresponding bonding wire 20, the trench T, and the alignment pad 117 may be arranged on the same line in the plan view. In at least one embodiment, the alignment pattern AP may have a width of about 15 μm to about 20 μm.

In at least one embodiment, the alignment pattern AP may include a lower material layer AP1, an intermediate material layer AP2, and an upper material layer AP3 being sequentially stacked. The lower material layer AP1, the intermediate material layer AP2, and the upper material layer AP3 of the alignment pattern AP may include the same material as that of the lower conductive layer BP1, the intermediate conductive layer BP2, and the upper conductive layer of the bonding pad BP, respectively. For example, the lower material layer AP1 may include nickel (Ni), the intermediate material layer AP2 may include palladium (Pd), and the upper material layer AP3 may include gold (Au). A thickness of the upper material layer AP3 may be greater than thicknesses of the lower material layer AP1 and the intermediate material layer AP2. In FIG. 3, upper surfaces of the lower material layer AP1, the intermediate material layer AP2, and the upper material layer AP3 are illustrated to be parallel to the upper surface of the substrate 110, but are not limited thereto. In at least one embodiment, as illustrated in FIG. 4, upper surfaces of the lower material layer AP1, the intermediate material layer AP2, and the upper material layer AP3 in the cross-sectional view illustrated in FIG. 3 may be convex. The trench T may not be formed in the alignment pattern AP, and the alignment pattern AP may not contact the bonding wire 20.

The external connection terminal 130 may be disposed below the substrate 110. The external connection terminal 130 may contact the lower pad 118 and may be electrically connected to the substrate 110. The external connection terminal 130 may be electrically connected to an external device, such as a main board. For example, the external connection terminal 130 may be a solder ball, a conductive bump, and/or a grid array (such as a pin grid array, a ball grid array, a land grid array, etc.).

The semiconductor chip 10 may further include a body portion 12 and a passivation layer 14. The body portion 12 may include a semiconductor material, for example, a group IV semiconductor, a group III-V compound semiconductor, a group II-VI compound semiconductor, and/or the like. For example, the group IV semiconductor may include silicon, germanium or silicon-germanium. The passivation layer 14 may cover an upper surface of the body portion 12 and may cover a side surface of the chip pad CP.

The semiconductor package 100 may further include an adhesive layer 140 covering a lower surface of the semiconductor chip 10. The adhesive layer 140 may be used to attach the semiconductor chip 10 to the substrate 110. For example, the adhesive layer 140 may be (and/or include) a die attach film (DAF).

The semiconductor package 100 may further include an encapsulant 150 covering the substrate 110 and the semiconductor chip 10. The encapsulant 150 may be a resin including epoxy or polyimide. For example, the resin may be a bisphenol-group epoxy resin, a polycyclic aromatic epoxy resin, an o-Cresol novolac epoxy resin, a biphenyl-group epoxy resin, naphthalene-group epoxy resin, and/or the like.

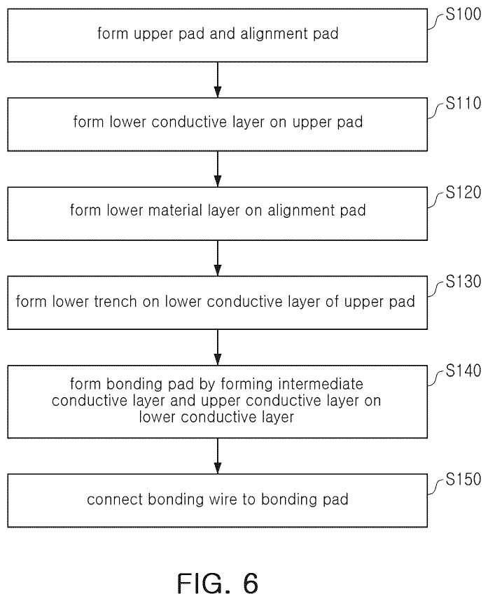

FIG. 6 is a flow chart of a method of manufacturing a semiconductor package according to embodiments.

Referring to FIG. 6, the method of manufacturing a semiconductor package may include forming an upper pad 116 and an alignment pad 117 (S100), forming a lower conductive layer BP1 on the upper pad 116 (S110), forming a lower material layer AP1 on the alignment pad 117 (S120), forming a lower trench T1 in the lower conductive layer BP1 on the upper pad 116 (S130), forming an intermediate conductive layer BP2 and an upper conductive layer BP3 on the lower conductive layer BP1 to form a bonding pad BP (S140), and connecting a bonding wire 20 to the bonding pad BP (S150).

The forming of the upper pad 116 and the alignment pad 117 (S100) may include forming a metal layer on the body portion 112 of the substrate 110 and patterning the metal layer. The upper pad 116 may be formed to be connected to one of the vias 115 of the substrate 110, and the alignment pad 117 may be formed to not be connected to the via 115. When viewed from above, the upper pad 116 may have a major axis and a minor axis such that the upper pad 116 extends in one direction. The alignment pad 117 may have a polygonal shape (such as a square or a triangle) and/or another shape (such as a circle or an ellipse). The upper pad 116 and the alignment pad 117 may include a conductive material, such as copper (Cu), aluminum (Al), silver (Ag), tin (Sn), gold (Au), nickel (Ni), lead (Pb), titanium (Ti), chromium (Cr), tungsten (W), alloys thereof, and/or the like. In at least one embodiment, the upper pad 116 may include the same material as the alignment pad 117. For example, the upper pad 116 and the alignment pad 117 may include copper (Cu).

The forming of the lower conductive layer BP1 on the upper pad 116 (S110) and the forming of the lower material layer AP1 on the alignment pad 117 (S120) may include performing a plating process. A metal material may be formed on the upper pad 116 by the plating process to form the lower conductive layer BP1, and a metal material may be formed on the alignment pad 117 to form the lower material layer AP1. In at least one embodiment, the forming of the lower conductive layer BP1 on the upper pad 116 (S110) and the forming of the lower material layer AP1 on the alignment pad 117 (S120) may be performed simultaneously. The lower material layer AP1 may include the same material as that of the lower conductive layer BP1, and, in at least one embodiment, may include nickel (Ni).

The forming of the lower trench T1 in the lower conductive layer BP1 on the upper pad 116 (S130) may include performing laser etching. The alignment pad 117 and the lower material layer AP1 formed thereon may be used as reference points for laser etching. For example, two alignment pads 117 may be disposed with the upper pad 116 interposed therebetween, and laser etching may be performed on a partial region of the upper pad 116 between the alignment pads 117. In at least one embodiment, one alignment pad 117 may be disposed to be adjacent to the upper pad 116, and laser etching may be performed using the one alignment pad 117 as a reference point. The lower trench T1 may be formed on an upper surface of the lower conductive layer BP1 by the laser etching process. The lower trench T1 may extend in the direction of the major axis of the upper pad 116, and in at least one embodiment, the maximum horizontal length of the lower trench T1 may be smaller than the maximum horizontal length of the upper pad 116.

The intermediate conductive layer BP2 and the upper conductive layer BP3 may be formed on the lower conductive layer BP1, thereby manufacturing the bonding pad BP (S140). The intermediate conductive layer BP2 and the upper conductive layer BP3 may be formed through a plating process. The intermediate conductive layer BP2 may cover the lower trench T1 of the lower conductive layer BP1 and may have an intermediate trench T2 overlapping the lower trench T1. The upper conductive layer BP3 may cover the intermediate trench T2 of the intermediate conductive layer BP2 and may have an upper trench T3 overlapping the intermediate trench T2. The upper trench T3 may be referred to as a trench T of the bonding pad BP.

In at least one embodiment, metal layers may also be formed on the lower material layer AP1 by the plating process, and the alignment pattern AP may be manufactured. The metal layers may be referred to as an intermediate material layer AP2 and an upper material layer AP3. The intermediate material layer AP2 and the upper material layer AP3 may include the same material as that of the intermediate conductive layer BP2 and the upper conductive layer BP3, respectively.

Subsequently, the semiconductor chip 10 may be mounted on the substrate 110 by connecting the bonding wire 20 to the bonding pad BP (S150). In at least one embodiment, the semiconductor chip 10 may be mounted on the substrate 110 by wire bonding. For example, a bonding wire 20 connecting the chip pad CP disposed on the upper surface of the semiconductor chip 10 to the bonding pad BP disposed on the upper surface of the substrate 110 may be formed by using a capillary. The stitch portion 28 of the bonding wire 20 may contact the bonding pad BP, and the stitch portion 28 may partially fill an inner wall of the trench T of the bonding pad BP. After the semiconductor chip 10 is mounted on the substrate 110, an encapsulant 150 covering the semiconductor chip 10 and an external connection terminal 130 may be formed on the bottom of the substrate 110 to manufacture a semiconductor package 100.

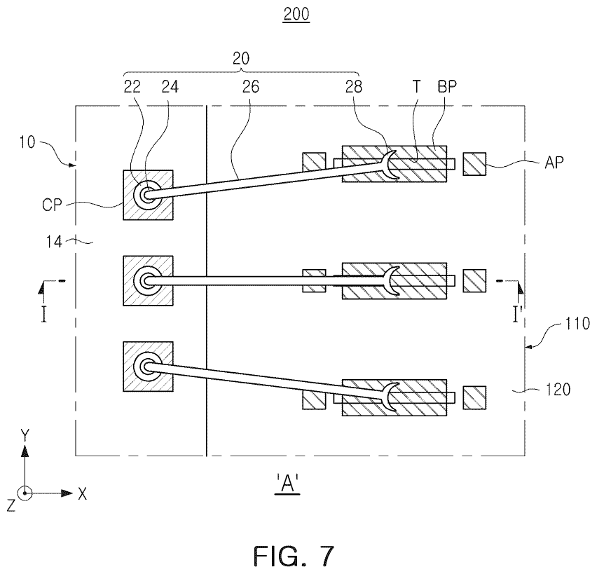

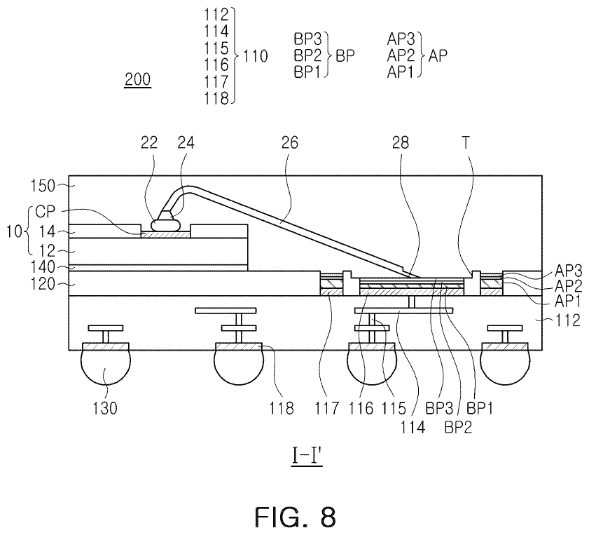

FIG. 7 is a plan view of a semiconductor package according to embodiments. FIG. 8 is a vertical cross-sectional view of the semiconductor package illustrated in FIG. 7, taken along line I-I′.

Referring to FIGS. 7 and 8, a semiconductor package 200 may include bonding pads BP and alignment patterns AP disposed on the upper surface of the substrate 110. In at least one embodiment, the trench T may be formed to be longer than the bonding pad BP. For example, the maximum horizontal length of the trench T may be greater than the maximum horizontal length of the bonding pad BP. The trench T may further extend toward (and/or into) the passivation layer 120, and an upper surface of the passivation layer 120 may have a step. An upper surface of the bonding pad BP and a portion of the upper surface of the passivation layer 120 may define a bottom surface of the trench T.

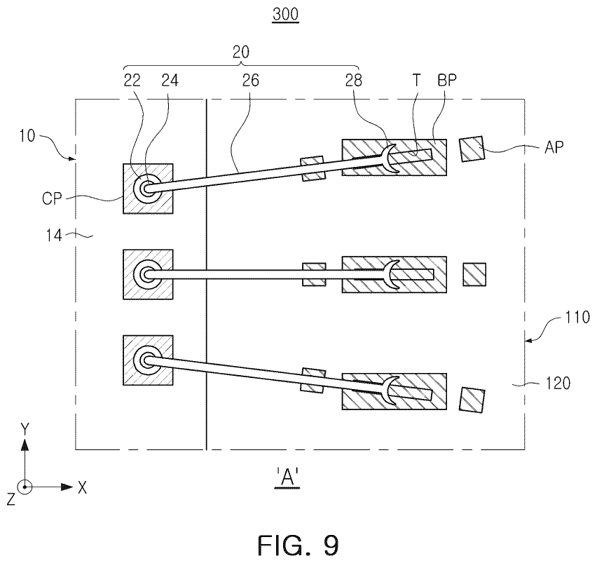

FIGS. 9 to 12 are plan views of semiconductor packages according to embodiments.

Referring to FIG. 9, a semiconductor package 300 may include bonding pads BP and alignment patterns AP disposed on the upper surface of the substrate 110. In at least one embodiment, the trench T formed on the upper surface of the bonding pad BP may be disposed to be aligned with a direction in which the wire portion 26 of the bonding wire 20 connected to the bonding pad BP extends in the plan view. The trenches T formed in each bonding pad BP may extend in the same direction as (e.g., a direction parallel to) a direction in which each bonding pad BP extends, or in a different direction (e.g., a direction not parallel to the direction in which each bonding pad BP extends, an intersecting direction, or a direction forming an angle). Since the trenches T are formed to extend in a direction parallel to the direction in which the wire portion 26 extends, a contact area between the stitch portion 28 and the trench T may be further increased, and thus, bonding strength of the bonding wire 20 may be increased. In at least one embodiment, different from the illustration, the trench T may further extend toward (and/or into) the passivation layer 120, and an upper surface of the passivation layer 120 may have a step.

In at least one embodiment, two adjacent alignment patterns AP may be disposed for each bonding pad BP, and the two alignment patterns AP may be spaced apart from each other in a direction parallel to the direction in which the wire portion 26 of the bonding wire 20 adjacent thereto extends. As described above, the alignment patterns AP may be used as reference points for laser etching to form the trench T.

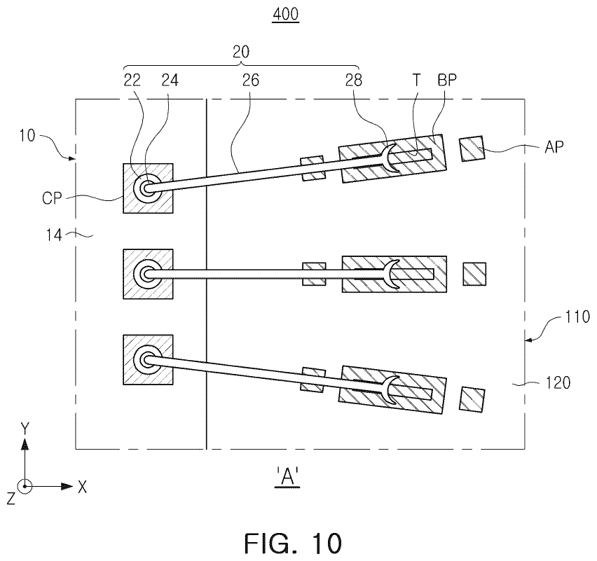

Referring to FIG. 10, the semiconductor package 400 may include bonding pads BP and alignment patterns AP disposed on the upper surface of the substrate 110. In at least one embodiment, compared to the embodiment of FIG. 9, each bonding pad BP may be disposed to be aligned with the direction in which the wire portion 26 of the bonding wire 20 connected to each bonding pad BP extends. For example, each bonding pad BP may extend in a direction parallel to a direction in which the wire portion 26 of the bonding wire 20 connected thereto extends. In at least one embodiment, different from the illustration, the trench T may further extend toward (and/or into) the passivation layer 120, and an upper surface of the passivation layer 120 may have a step.

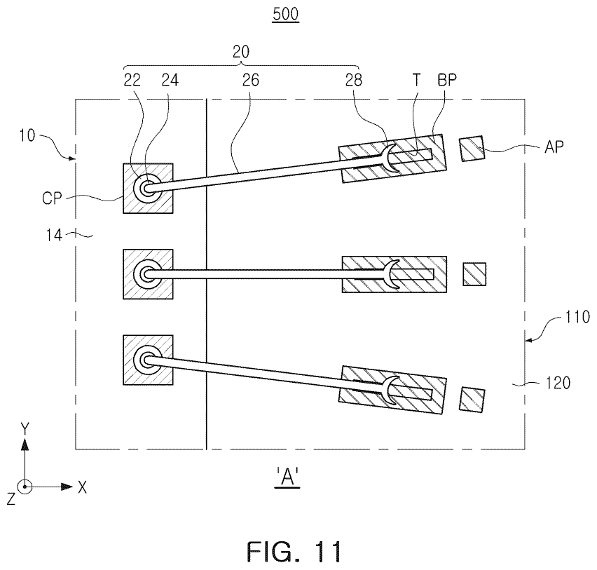

Referring to FIG. 11, a semiconductor package 500 may include bonding pads BP and alignment patterns AP disposed on the upper surface of the substrate 110. In at least one embodiment, compared to the embodiment of FIG. 10, one adjacent alignment pattern AP may be disposed for each bonding pad BP. For example, each bonding pad BP may be disposed between an adjacent alignment pattern AP and a chip pad CP, and the alignment pattern AP may be disposed farther away from the chip pad CP than the bonding pad BP. In at least one embodiment, each alignment pattern AP may be disposed between the bonding pad BP and the chip pad CP adjacent thereto, and the alignment pattern AP may be disposed to be closer to the chip pad CP than to the bonding pad BP. In at least one embodiment, different from the illustration, the trench T may further extend toward (and/or into) the passivation layer 120, and an upper surface of the passivation layer 120 may have a step.

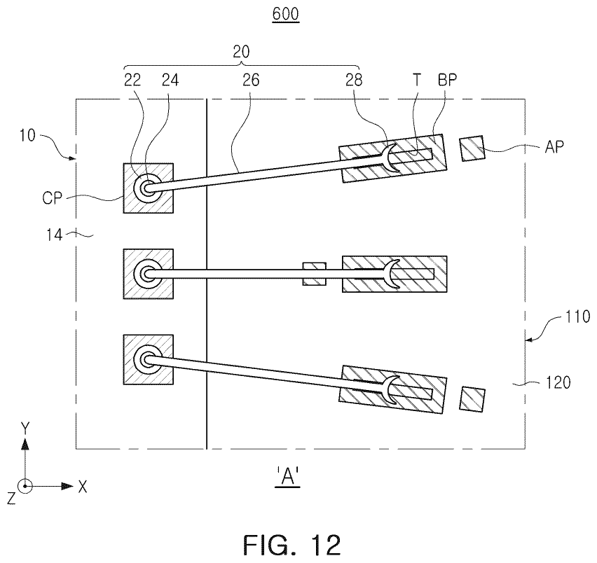

Referring to FIG. 12, a semiconductor package 600 may include bonding pads BP and alignment patterns AP disposed on the upper surface of the substrate 110. In at least one embodiment, compared to the embodiment of FIG. 11, some alignment patterns AP may be disposed farther from the chip pad CP than the bonding pad BP, and some alignment patterns AP may be disposed to be closer to the chip pad CP than to the bonding pad BP. In at least one embodiment, different from the illustration, the trench T may further extend toward (and/or into) the passivation layer 120, and an upper surface of the passivation layer 120 may have a step.

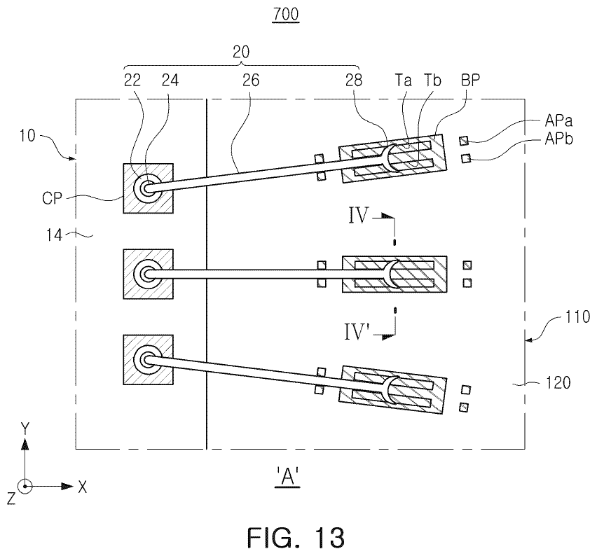

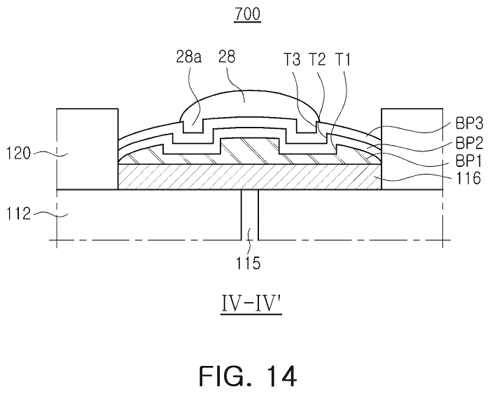

FIG. 13 is a plan view of a semiconductor package according to embodiments. FIG. 14 is a vertical cross-sectional view of the semiconductor package illustrated in FIG. 13, taken along line IV-IV′.

Referring to FIGS. 13 and 14, a semiconductor package 700 may include bonding pads BP and alignment patterns AP disposed on the upper surface of the substrate 110. In at least one embodiment, a plurality of trenches Ta and Tb may be formed on the upper surface of each bonding pad BP. For example, two trenches Ta and Tb may be formed on the upper surface of each bonding pad BP, and the trenches Ta and Tb may extend in the direction of the major axis of the bonding pad BP and may be spaced apart from each other in the direction of the minor axis of the bonding pad BP. The stitch portion 28 of the bonding wire 20 may contact the bonding pad BP. In the cross-sectional view, the plurality of upper trenches T3 may correspond to the trenches Ta and Tb, respectively. The stitch portion 28 may include a plurality of protrusions 28a partially filling inner walls of the plurality of upper trenches T3 of the bonding pad BP.

In at least one embodiment, four adjacent alignment patterns AP may be disposed in two pairs for each bonding pad BP. The pair of alignment patterns APa and APb may be spaced apart from each other in the direction of the minor axis of adjacent bonding pads BP, and the pairs of alignment patterns APa and APb may be spaced apart from each other in the direction of the major axis of the bonding pad BP with the bonding pad BP interposed therebetween. The alignment patterns APa and APb may be used as reference points for laser etching to form the plurality of trenches Ta and Tb. In at least one embodiment, different from the illustration, the trenches Ta and Tb may further extend toward (and/or into) the passivation layer 120, and an upper surface of the passivation layer 120 may have a step.

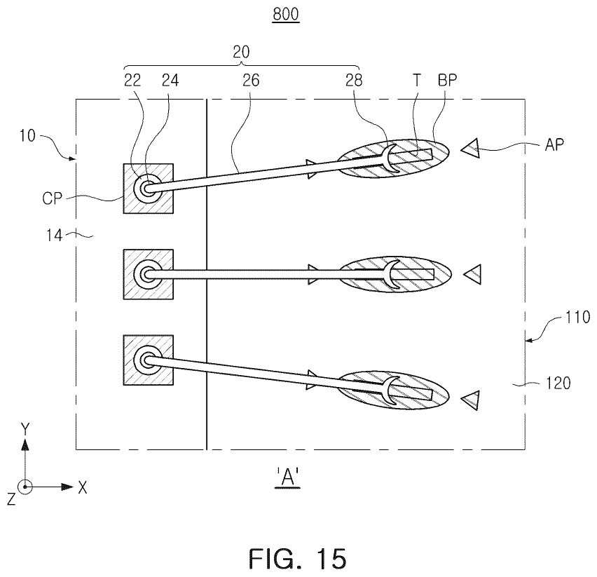

FIG. 15 is a plan view of a semiconductor package according to embodiments.

Referring to FIG. 15, a semiconductor package 800 may include bonding pads BP and alignment patterns AP disposed on the upper surface of the substrate 110. In at least one embodiment, in the plan view, the bonding pad BP may have an elliptical shape having a major axis and a minor axis. In at least one embodiment, in the plan view, the alignment pattern AP may have a triangular shape, but is not limited thereto. For example, in some embodiments, the alignment pattern AP may have various shapes, such as a cross shape, a Y shape, an arrow shape, an ellipse, etc.

According to the embodiments of the inventive concepts, the semiconductor package may include the alignment pattern disposed to be adjacent to the bonding pad. Since the bonding pad includes the trench formed to be aligned with the alignment pattern, a contact area with the bonding wire may increase. Accordingly, bonding force between the bonding wire and the bonding pad may increase.

While embodiments have been illustrated and described above, it will be apparent to those skilled in the art that modifications and variations could be made without departing from the scope of the present inventive concepts as defined by the appended claims.

What is claimed is:

1. A semiconductor package comprising:
a substrate including an upper pad and at least one alignment pad on an upper surface of the substrate such that the upper pad is adjacent to the at least one alignment pad;
a first bonding pad on the upper pad, the first bonding pad including a first trench on an upper surface of the first bonding pad, the first trench extending in a first direction;
at least one first alignment pattern on the at least one alignment pad such that the at least one first alignment pattern is adjacent to the first bonding pad and the at least one first alignment pattern is aligned with the first trench in the first direction;
a semiconductor chip on the substrate; and
a first bonding wire connecting the semiconductor chip to the first bonding pad, the first bonding wire contacting the first bonding pad and partially filling the first trench.

2. The semiconductor package of claim 1, wherein
the first bonding pad includes a lower conductive layer, an intermediate conductive layer, and an upper conductive layer sequentially stacked on the upper pad, and
the at least one first alignment pattern includes a lower material layer, an intermediate material layer, and an upper material layer being sequentially stacked.

3. The semiconductor package of claim 2, wherein the lower material layer, the intermediate material layer, and the upper material layer, respectively, include a same material as the lower conductive layer, the intermediate conductive layer, and the upper conductive layer.

4. The semiconductor package of claim 2, wherein a thickness of the lower conductive layer is within a range of 3 μm to 10 μm.

5. The semiconductor package of claim 2, wherein
a thickness of the intermediate conductive layer is within a range of 1 μm to 2 μm, and
a thickness of the upper conductive layer is within a range of 1 μm to 2 μm.

6. The semiconductor package of claim 1, wherein the first bonding pad includes
a lower conductive layer including a lower trench,
an intermediate conductive layer including an intermediate trench overlapping the lower trench, and
an upper conductive layer including the first trench, the first trench overlapping the intermediate trench.

7. The semiconductor package of claim 6, wherein a depth of the lower trench is within a range of 1 μm to 5 μm.

8. The semiconductor package of claim 1, wherein the at least one first alignment pattern includes at least two first alignment patterns spaced apart from each other in the first direction such that the first bonding pad is interposed between the at least two first alignment patterns.

9. The semiconductor package of claim 1, further comprising:
a passivation layer covering the upper surface of the substrate and covering side surfaces of the first bonding pad and the at least one first alignment pattern,
wherein the first trench further extends toward the passivation layer such that an upper surface of the passivation layer has a step.

10. The semiconductor package of claim 1, further comprising:
a second bonding pad on a second upper pad, the second bonding pad including a second trench;
at least one second alignment pattern disposed on the at least one alignment pad such that the at least one second alignment pattern is adjacent to the second bonding pad; and
a second bonding wire connecting the semiconductor chip to the second bonding pad.

11. The semiconductor package of claim 10, wherein the second trench extends in a direction parallel to the first direction.

12. The semiconductor package of claim 10, wherein
the second trench extends in a direction different from the first direction,
a wiring portion of the first bonding wire extends in the first direction, and
a wiring portion of the second bonding wire extends in the direction in which the second trench extends.

13. The semiconductor package of claim 12, wherein the first bonding pad extends in a direction not parallel to the first direction.

14. The semiconductor package of claim 10, wherein the at least one first alignment pattern includes a plurality of first alignment patterns such that the plurality of first alignment patterns are disposed farther from the semiconductor chip than the first bonding pad.

15. The semiconductor package of claim 14, wherein the at least one second alignment pattern is disposed closer to the semiconductor chip than the second bonding pad.

16. A semiconductor package comprising:
a substrate including an upper pad and at least one alignment pad on an upper surface of the substrate such that the upper pad is adjacent to the at least one alignment pad;
a bonding pad on the upper pad, the bonding pad including a trench on an upper surface of the bonding pad, and extending in a first direction;
at least one alignment pattern on the at least one alignment pad such that the at least one alignment pattern is adjacent to the bonding pad and the at least one alignment pattern is aligned with the trench in the first direction;
a semiconductor chip on the substrate and including a chip pad; and
a bonding wire connecting the chip pad to the bonding pad, the bonding wire including a stitch portion contacting the bonding pad and a wire portion between the stitch portion and the chip pad,
wherein the stitch portion includes a protrusion partially filling the trench, and
a width of the at least one alignment pattern is within a range of 15 μm to 20 μm.

17. The semiconductor package of claim 16, wherein a maximum horizontal width of the stitch portion is greater than a width of the wire portion.

18. A method of manufacturing a semiconductor package, the method comprising:
forming an upper pad and at least one alignment pad adjacent to the upper pad on a substrate;
forming a lower conductive layer on the upper pad;
forming a lower material layer on the alignment pad;
forming a lower trench in the lower conductive layer by performing a laser etching process using the at least one alignment pad as a reference point;
forming an intermediate conductive layer covering the lower conductive layer, the intermediate conductive layer having an intermediate trench;
forming a bonding pad by forming an upper conductive layer covering the intermediate conductive layer, the upper conductive layer having an upper trench;
forming an alignment pattern by forming an intermediate material layer and an upper material layer on the lower material layer; and
connecting a bonding wire to the bonding pad such that the bonding wire contacts the bonding pad and partially fills an inner wall of the upper trench,
wherein the alignment pattern is aligned with the upper trench in a first direction in which the upper trench extends.

19. The method of claim 18, wherein the lower conductive layer and the lower material layer are simultaneously formed by a plating process.

20. The method of claim 18, wherein the lower material layer, the intermediate material layer, and the upper material layer, respectively, include a same material as a material of the lower conductive layer, the intermediate conductive layer, and the upper conductive layer.
